(19) United States
(12) Patent Application Publication
(10) Pub. No.: US 2026/0052625 A1
(43) Pub. Date: Feb. 19, 2026

(54) CIRCUIT BOARD

(71) Applicant: JPC connectivity Inc., New Taipei City (TW)

(72) Inventors: Wen-Yu WANG, New Taipei City (TW); Zhong-Lin LI, New Taipei City (TW)

(21) Appl. No.: 18/961,857

(22) Filed: Nov. 27, 2024

(30) Foreign Application Priority Data
Aug. 19, 2024 (TW) 113131073

(51) Int. Cl. H05K 1/02

(52) U.S. Cl. CPC H05K 1/0245; H05K 2201/09227; H05K 2201/09672

(57) ABSTRACT

A circuit board includes a pair of first signal terminals, a pair of second signal terminals, a first trace, and a second trace. The pair of first signal terminals include a first terminal and a second terminal. The pair of second signal terminals include a third terminal and a fourth terminal. A distance between the first terminal and the fourth terminal is not equal to a distance between the second terminal and the third terminal. A length of the first trace is substantially equal to a length of the second trace. The first trace and the second trace extend to a second specific layer through vias from a first specific layer of the circuit board so that the first terminal is electrically connected to the third terminal and the second terminal is electrically connected to the fourth terminal.

### BACKGROUND

### Technical Field

The present disclosure relates to a circuit board, and more particularly to a side-exit circuit board is designed for use with cables or connectors.

### Description of Related Art

The statements in this section merely provide background information related to the present disclosure and do not necessarily constitute prior art.

The side-exit paddle card is mainly a circuit board 100 with a corner, and is more commonly used in the field of connectors, and is particularly suitable for use as the internal paddle card of Type-C connectors. Therefore, the side-exit paddle card is mainly used to connect MCIO (mini cool edge I/O) cables (or modular connectors thereof) and transfer to various specifications such as, but not limited to, Type-C ports. It is mainly used for high-speed transmission of signals, and the side-exit paddle cards generally have the characteristics of small size and high-density trace.

However, with reference to FIG. 1A, due to mechanical limitations of the side-exit paddle card, the differential pairs (internal and external traces) may be unequal in length, thereby causing a problem of signal transmission delay difference (skew). Therefore, the general solution is to use the design method as shown in FIG. 1B and use serpentine wiring to solve the problem of unequal lengths of differential pairs. However, for traces with shorter distances (such as traces closer to corners), too many serpentine wirings cannot be used to maintain the same length. The main reason is that the paths of short-distance traces are too short, making it difficult to form sufficient and standard serpentine wiring (the leftmost half of the wiring can only form two serpentine wiring as shown in FIG. 1B) to solve the problem of unequal lengths of differential pairs. Therefore, if sufficient serpentine wiring cannot be formed, the differential pairs (internal and external traces) will still be unequal in length, resulting in signal transmission delay differences.

On the other hand, since the structure of the serpentine wiring will cause the differential pairs to be asymmetrical, the differential pairs (internal and external traces) are not parallel and equidistant structures. Therefore, it will cause poor common-mode conversion (SCD21) and high attenuation (insertion loss; IL, or SDD21) as shown in FIGS. 1C to 1D and FIGS. 1E to 1F. Specifically, in FIGS. 1C and 1D, the test waveform diagrams of SCD21 and SDD21 of the differential pairs Df1, Df2 farthest from the corner are mainly shown. Since the differential pairs Df1, Df2 are far away from the corners, there is enough distance to form sufficient serpentine wiring, its test waveform can meet the specifications (that is, the waveform of SCD21 is below the upper limit value Vm, and the two lines of SDD21 do not intersect). However, since the differential pairs Df3, Df4 closest to the corners do not have enough distance to form sufficient serpentine wiring, the test waveform cannot meet the specifications, resulting in the risk of distortion in the transmission of differential signals.

Therefore, how to design a circuit board so that the traces of differential pairs at the corners can be of equal length without using serpentine wiring has become a critical topic in this field.

### SUMMARY

In order to solve the above-mentioned problems, the present disclosure provides a circuit board. The circuit board includes a pair of first signal terminals, a pair of second signal terminals, and a first trace assembly. The pair of first signal terminals include a first terminal and a second terminal. The first terminal and the second terminal are arranged in a specific direction from an edge of the circuit board, and the first terminal and the second terminal form on a first side of the circuit board. The pair of second signal terminals include a third terminal and a fourth terminal. The third terminal and the fourth terminal are arranged in the specific direction, wherein a first shortest distance between the first terminal and the fourth terminal is not the same as a second shortest distance between the second terminal and the third terminal. The first trace assembly includes a first trace and a second trace. The first trace is formed on a first specific layer of the board circuit, extends to a second specific layer of the board circuit through one of a plurality of first vias, and returns to the first specific layer through another of the plurality of first vias so as to electrically connect to the first terminal and the third terminal. The second trace is formed on the first specific layer, extends to the second specific layer through one of a plurality of second vias, and returns to the first specific layer through another of the plurality of second vias so as to electrically connect to the second terminal and the fourth terminal. The first trace has a first length and the second trace has a second length. The first trace and the second trace are formed on different layers in a staggered structure, and the first length is substantially equal to the second length.

The main purpose and effect of the present disclosure is that the disclosed feature of the trace entering the inner layer of the circuit board through the vias allows for length compensation to be performed on traces on different layers, which ensures that the first length of the first trace is substantially equal to the second length of the second trace, thereby achieving effects of better common-mode conversion and reduced attenuation.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

FIG. 1A is a schematic diagram of the circuit structure of a conventional side-exit paddle card.

FIG. 1B is a schematic diagram of the circuit structure of another conventional side-exit paddle card.

FIGS. 1C to 1D are test waveform diagrams of the differential pair farthest from the corner in the circuit structure of FIG. 1B.

FIGS. 1E to 1F are test waveform diagrams of the differential pair closest to the corner in the circuit structure of FIG. 1B.

FIG. 2A is a diagram of the trace layout of the side-exit circuit board according to a first embodiment of the present disclosure.

FIG. 2B is a diagram of the trace layout of the side-exit circuit board according to a second embodiment of the present disclosure.

FIG. 2C is a diagram of the trace layout of the side-exit circuit board according to a third embodiment of the present disclosure.

FIG. 3A is a diagram of the one trace layout of the side-exit circuit board according to a fourth embodiment of the present disclosure.

FIG. 3B is a diagram of the another trace layout of the side-exit circuit board according to a fourth embodiment of the present disclosure.

FIG. 3C is a diagram of the trace layer of overlapping circuits of FIG. 3A and FIG. 3B according to the fourth embodiment of the present disclosure.

FIG. 4A is a diagram of the one trace layout of the side-exit circuit board according to a fifth embodiment of the present disclosure.

FIG. 4B is a diagram of the another trace layout of the side-exit circuit board according to a fifth embodiment of the present disclosure.

FIG. 4C is a diagram of the trace layer of overlapping circuits of FIG. 4A and FIG. 4B according to the fifth embodiment of the present disclosure.

### DETAILED DESCRIPTION

Reference will now be made to the drawing figures to describe the present disclosure in detail. It will be understood that the drawing figures and exemplified embodiments of present disclosure are not limited to the details thereof.

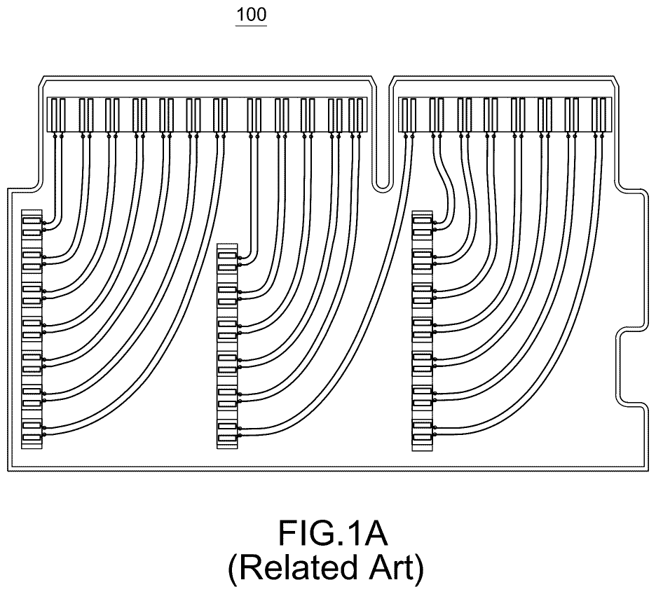

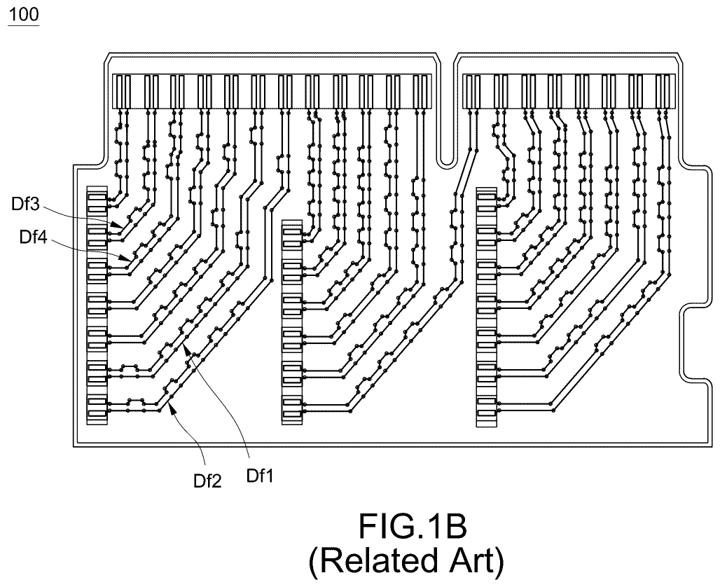

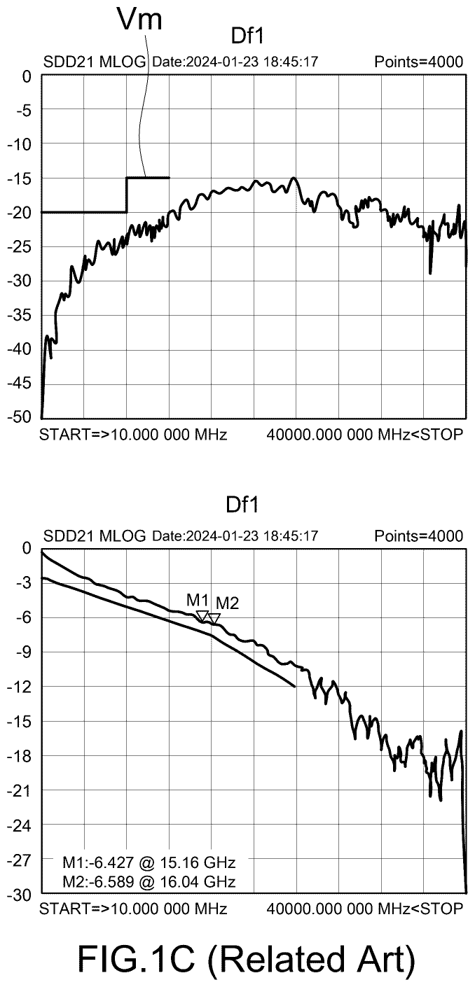

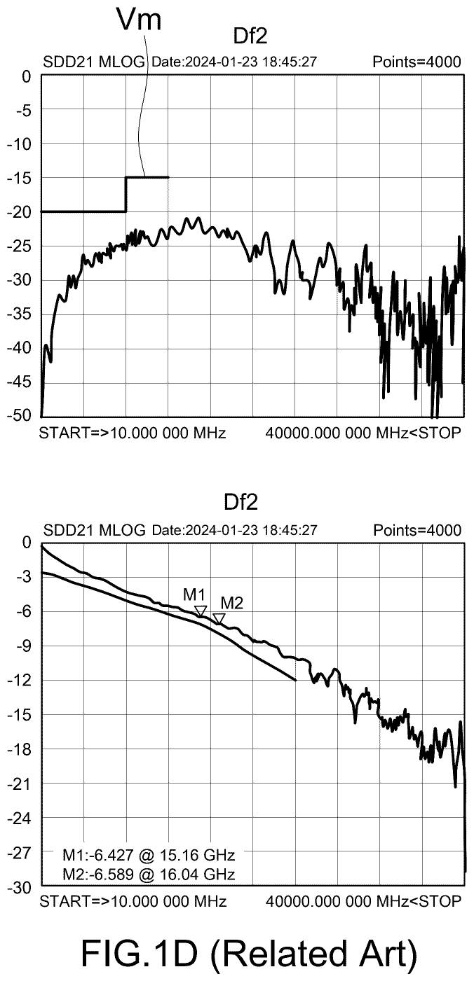

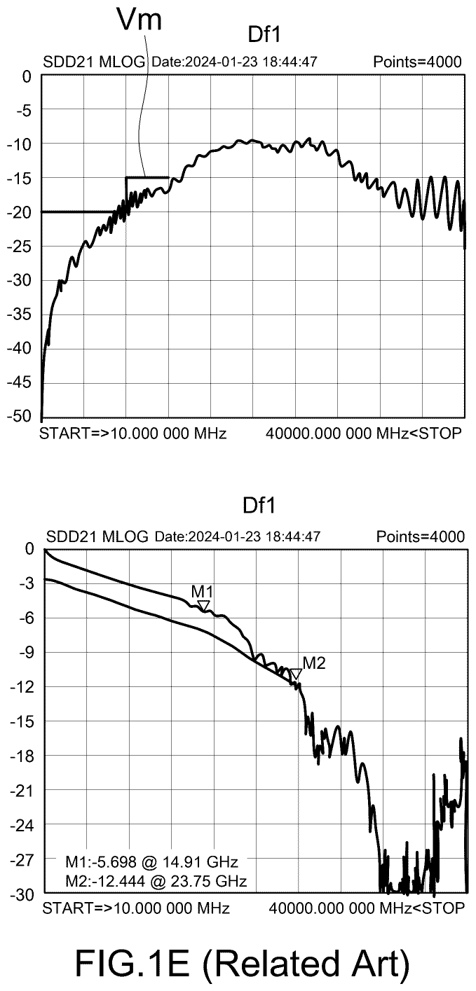

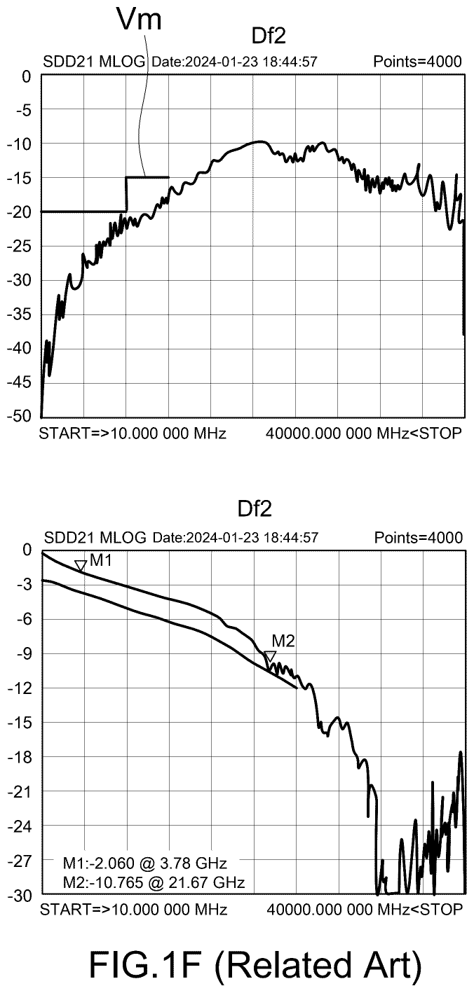

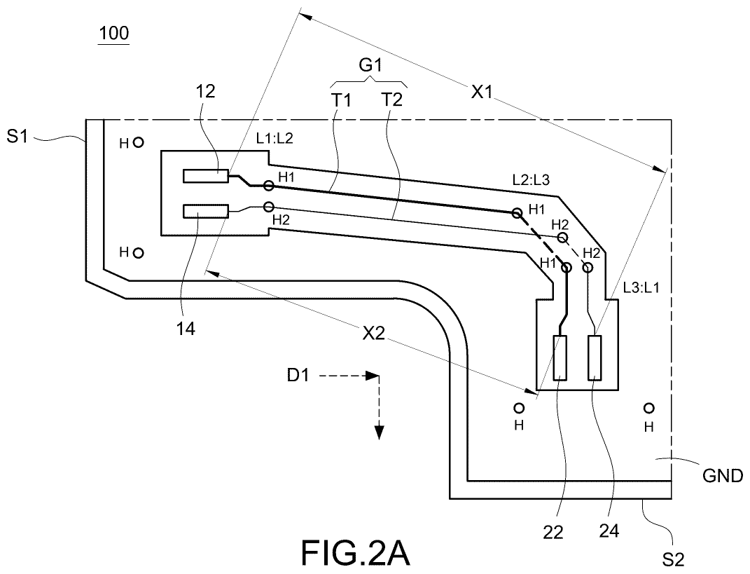

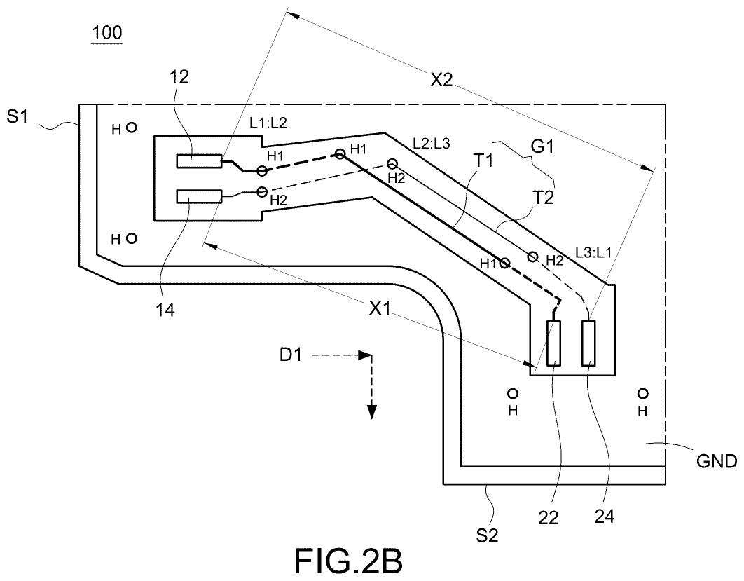

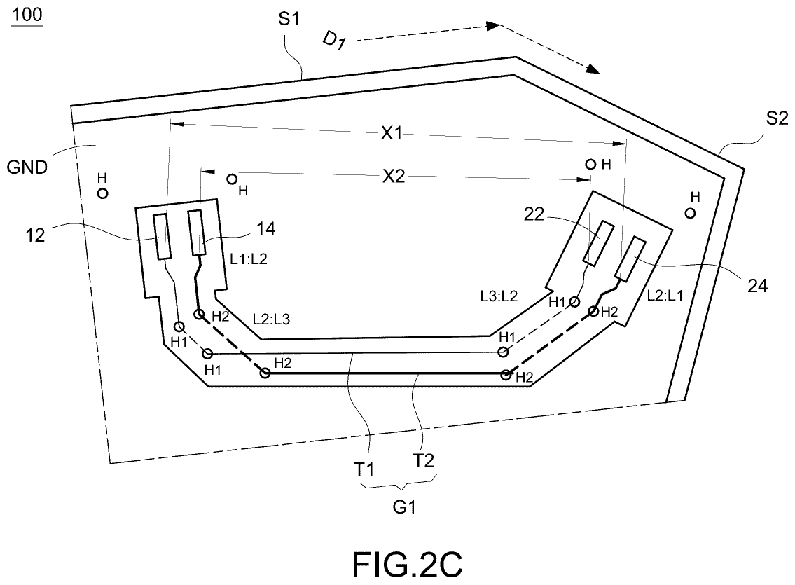

Please refer to FIG. 2A, which shows a diagram of the trace layout of the side-exit circuit board according to a first embodiment of the present disclosure, and also refer to FIG. 1A to FIG. 1F. In order to clarify the characteristics of the present disclosure, the circuit board 100 mainly uses a corner structure of the circuit board 100 with a substantially 90-degree angle as an illustrative example, but it is not limited to the present disclosure. In FIG. 2A, the circuit board 100 includes a pair of first signal terminals and a pair of second signal terminals. The pair of first signal terminals include a first terminal 12 and a second terminal 14 arranged in a specific direction D1 from an edge of the circuit board 100. In particular, the specific direction D1 is only an illustrative example, and it may also be opposite to the direction shown in FIG. 2A. The first terminal 12 and the second terminal 14 form on a first side S1 of the circuit board 100, and the third terminal 22 and the fourth terminal 24 form on a second side S2 of the circuit board 100. Alternatively, as shown in FIG. 1A and FIG. 1B, the middle terminals of the circuit board are not formed on any side of the circuit board 100. Therefore, if the terminals are arranged in the specific direction D1, the sequence is the first terminal 12, the second terminal 14, the third terminal 22, and the fourth terminal 24.

In particular, the connection formed by a first shortest distance X1 from the first terminal 12 to the fourth terminal 24 is different from the connection formed by a second shortest distance X2 from the second terminal 14 to the third terminal 22. It means that the pair of first signal terminals and the pair of second signal terminals are not formed on two opposite sides of the circuit board 100. This prerequisite is that the two opposite sides of the circuit board 100 be parallel, and this does not apply if the two opposing sides of the circuit board 100 are not parallel. Also, there is no situation where the third terminal 22 and the fourth terminal 24 are formed on the left and right of the circuit board 100 (the same is true for the first terminal 12 and the second terminal 14). Therefore, the connection formed by the first shortest distance X1 may be smaller or larger than the connection formed by the second shortest distance X2. The main reason is that terminals closer to the corners of the circuit board 100 are bound to have shorter distances (as shown in FIG. 2A, the connection formed by the shortest distance from the second terminal 14 to the third terminal 22 is shorter).

In one embodiment, the third terminal 22 and the fourth terminal 24 form on the second side S2 of the circuit board 100. In addition, the first side S1 is obviously non-parallel to the second side S2, and the first side S1 and the second side S2 are adjacent sides, that is, the first side S1 is adjacent to the second side S2. In particular, the first side S1 and the second side S2 are substantially 90 degrees apart, that is, the first side S1 is substantially 90 degrees to the second side S2, but the angle is not limited. As long as the two are not parallel, both should be included in the scope of this embodiment.

Please refer to FIG. 2A again, the circuit board 100 further includes a first trace assembly G1, a plurality of vias H1, and a plurality of vias H2. The first trace assembly G1 includes a first trace T1 and a second trace T2. The first trace T1 is formed on a first specific layer (here represented by a first layer L1) of the circuit board 100, and the first trace T1 extends to a second specific layer (here represent by a second layer L2) of the circuit board 100 through one of a plurality of first vias H1. Moreover, regardless of the number of first vias H1 that the first trace T1 extends to different layers, it will ultimately return to the first specific layer through another first via H1 so that the first terminal 12 is electrically connected to the third terminal 22 through the first trace T1. In particular, the first trace T1 has a first length, and the first length refers to a total trace length of the first trace T1. Similarly, the second trace T2 is formed on the first specific layer, i.e., the first layer L1 of the circuit board 100, and the second trace T2 extends to the second specific layer (here represent by the second layer L2) of the circuit board 100 through one of a plurality of second vias H2. Moreover, regardless of the number of second vias H2 that the second trace T2 extends to different layers, it will ultimately return to the second specific layer through another second via H2 so that the second terminal 14 is electrically connected to the fourth terminal 24 through the second trace T2. In particular, the second trace T2 has a second length, and the second length refers to a total trace length of the second trace T2. Moreover, the vias H1, H2 may be configured as through holes, blind holes, or buried holes, according to the specific requirements of the application. However, the vias H1, H2 are typically implemented as blind holes, and this configuration is not limited. In addition, conductive materials such as, but not limited to, tin, copper, etc. may be disposed inside the vias H1, H2 so that traces on different layers can be electrically connected through the vias H1, H2.

In FIG. 2A, “L1:L2” represents the vias from the first layer L1 (i.e., a surface layer L1) of the circuit board 100 to the second layer L2 thereof; “L2:L3” represents the vias from the second layer L2 of the circuit board 100 to the third layer L3 thereof. This process will be described in further detail, and the rest may be deduced by analogy and the detail description is omitted here for conciseness. Therefore, the first terminal 12 is coupled to the first trace T1, and the first trace T1 first extends from the surface layer L1 of the circuit board 100 through the first vias H1 to the second layer L2. Where the first trace T1 of the second layer L2 is intended to overlap with the second trace T2, the first trace T1 first extends from the second layer L2 to the third layer L3 through the first vias H1 to build a structure where traces overlap on different layers. Finally, the first trace T1 extends from the third layer L3 through the first vias H1 to the surface layer L1 to couple to the third terminal 22. As shown in FIG. 2A, the structure of the second trace T2 is similar to that of the first trace T1 and will not be described again here.

In particular, when the first trace T1 and the second trace T2 have the same length, the length of the first trace T1 on the surface layer L1 is shorter than that of the second trace T2. That is, at the intersection (overlap) of the first trace T1 and the second trace T2, the first trace T1 first extends through the first vias H1 to the third layer L3, and the second trace T2 crosses the first trace T1 of the third layer L3 on the surface layer L1, and then extends to the third layer L3 through the second vias H2. In one embodiment, the number of the first vias H1 and the second vias H2 is three respectively, but is not limited thereto. Mainly, after the first trace T1 and the second trace T2 are designed to overlap on different layers through the first vias H1 and the second vias H2, it is sufficient to ensure that the length of the first trace T1 and the length of the second trace T2 are substantially equal. In addition, the first vias H1 and the second vias H2 have a corresponding relationship (that is, they are equal in number) so that the overall number of the first vias H1 and the second vias H2 is an even number. Therefore, those skilled in the art can increase or decrease the number of first vias H1 and the second vias H2 according to the logic of the present disclosure, but basically at least one via needs to be arranged at the overlap of the first trace T1 and the second trace T2 to implement.

Therefore, the circuit board 100 of the present disclosure is characterized in that traces can be formed on different layers in a staggered structure through vias. Specifically, when the first trace T1 extends to the third layer L3, the length of the first trace T1 is decreased from being far away from the corner of the circuit board 100 to being close to the corner of the circuit board 100 (compared to the related technologies of FIG. 1A and FIG. 1B). Similarly, when the second trace T2 extends to the third layer L3, the length of the second trace T2 is increased from close to the corner of the circuit board 100 to away from the corner of the circuit board 100 (compared to the related technologies of FIG. 1A and FIG. 1B).

Therefore, through the disclosed feature of the traces entering the inner layer of the circuit board 100 through the via holes, length compensation can be performed on the traces on different layers, so that the first length of the first trace T1 is substantially equal to the length of the second trace T2 Second length. Accordingly, the disclosure of the feature whereby the arrangement enters the inner layers of the circuit board 100 through the vias enables the length compensation across different layers, thus ensuring that the first length of the first trace T1 is substantially equal to the second length of the second trace T2. The most significant difference between this structural feature and the circuit board structure depicted in FIG. 1A and FIG. 1B is that the first terminal 12 of the circuit board 100 is electrically connected to the fourth terminal 24 thereof, and the second terminal 14 of the circuit board 100 is electrically connected to the third terminal 22 thereof. However, the present disclosure is exactly the opposite, that is, the traces of the present disclosure enter the inner layers of the circuit board 100 through the vias so that the first terminal 12 of the present disclosure is electrically connected to the third terminal 22, and the second terminal 14 is electrically connected to the fourth terminal 24.

Furthermore, the circuit board 100 is designed to accommodate MCIO (mini cool edge I/O) cables (or modular connectors thereof) for connection and adaptation to ports of varying specifications, including, but not limited to, Type-C. It is not intended to serve as an interface for the circuit board 100. Therefore, the first trace assembly G1 may mainly be used to transmit differential signals. In the present disclosure, since the first length of the first trace T1 is substantially equal to the second length of the second trace T2, the differential pairs (i.e., the inner and outer traces of the first trace assembly G1) may be made substantially equal in length, which can reduce the problem of delay difference (skew) in signal transmission. Moreover, the present disclosure does not need to use serpentine wiring to solve the problem of unequal lengths of the differential pair (i.e., the first trace assembly G1) in order to make the two traces equal in length so as to solve the asymmetry of the differential pair (i.e., the first trace assembly G1). Therefore, the effect of providing better common-mode conversion (SCD21) and lower attenuation (insertion loss; IL, or SDD2) can be achieved.

Moreover, since the differential pair (i.e., the first trace assembly G1) mainly transmits high-speed differential signals, a better wiring manner is to arrange the two traces of the differential pair (i.e., the first trace assembly G1) as parallel and equidistant as possible to avoid the differential signal being affected by noises. Since the first trace assembly G1 of the present disclosure does not need to use serpentine wiring, and the lengths of the first trace T1 and the second trace T2 are substantially equal, the first trace T1 and the second trace T2 of the present disclosure may be substantially parallel and equidistant in the trace structure. That is, the first trace T1 and the second trace T2 of the present disclosure may form a parallel and equidistant trace structure on the linear extension section of the same layer.

In addition, the circuit board 100 in FIG. 2A further includes a ground layer (not shown in the figure). The ground layer may be formed on any layer except the surface layer L1, and no trace of the first trace assembly G1 is formed on the ground layer. Taking FIG. 2A as an example, the circuit board 100 is a four-layer board, the ground layer should be formed on the other surface layer L4. The ground layer may be electrically connected to a ground block GND of the surface layer L1 through the vias H, and can also be coupled to a ground terminal (not shown) through the ground block GND. Furthermore, the accurate value of the measurement signal depends on the consistency of the “ground” in the system, and therefore the circuit board 100 of the present disclosure is configured with a ground layer so that the transmitted differential signals have the same and referable ground potential and the quality of the transmitted signals can be better. In one embodiment, the number of vias H that can electrically connect the ground block GND of the surface layer L1 and the ground layer is only schematically marked as three, but in practice it is not limited to three, and it can be increased or decreased according to actual needs.

Please refer to FIG. 2B, which shows a diagram of the trace layout of the side-exit circuit board according to a second embodiment of the present disclosure, and also refer to FIG. 1A to FIG. 2A. The difference between FIG. 2B and FIG. 2A is that the paths of the first trace T1 and the second trace T2 are different, and the associated positions of the first vias H2 and the second vias H2 are also different. The first trace T1 and the second trace T2 may also be formed on different layers in a staggered structure through the first vias H1 and the second vias H2 so that the length of the first trace T1 is substantially equal to the length of the second trace T2 as shown in FIG. 2A. In particular, the structural description and characteristics of FIG. 2B are similar to those of FIG. 2A and will not be described again here.

Please refer to FIG. 2C, which shows a diagram of the trace layout of the side-exit circuit board according to a third embodiment of the present disclosure, and also refer to FIG. 1A to FIG. 2B. The difference between FIG. 2C and FIG. 2A is that the circuit board 100 is an irregular board, which mainly shows a relatively extreme embodiment. In FIG. 2C, an angle between the pair of first signal terminals and the pair of second signal terminals is not a 90-degree angle. However, the first trace T1 and the second trace T2 may also be formed on different layers in a staggered structure through the first vias H1 and the second vias H2 so that the length of the first trace T1 is substantially equal to the length of the second trace T2 as shown in FIG. 2A. In particular, the structural description and characteristics of FIG. 2C are similar to those of FIG. 2A and will not be described again here. Therefore, as shown in FIG. 2A to FIG. 2C, no matter what the shape of the side-exit circuit board 100 is, through the arrangement of the traces of the present disclosure, the lengths of the traces on different layers can be compensated to achieve corresponding effects.

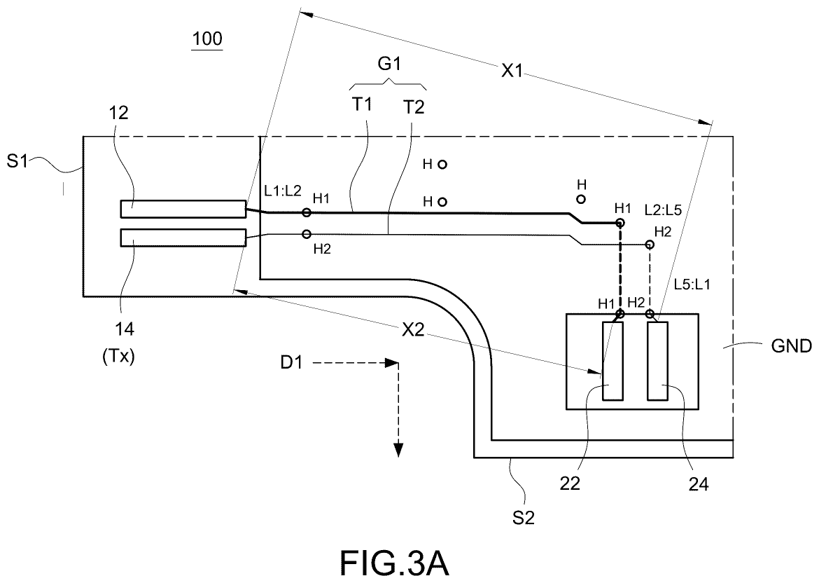

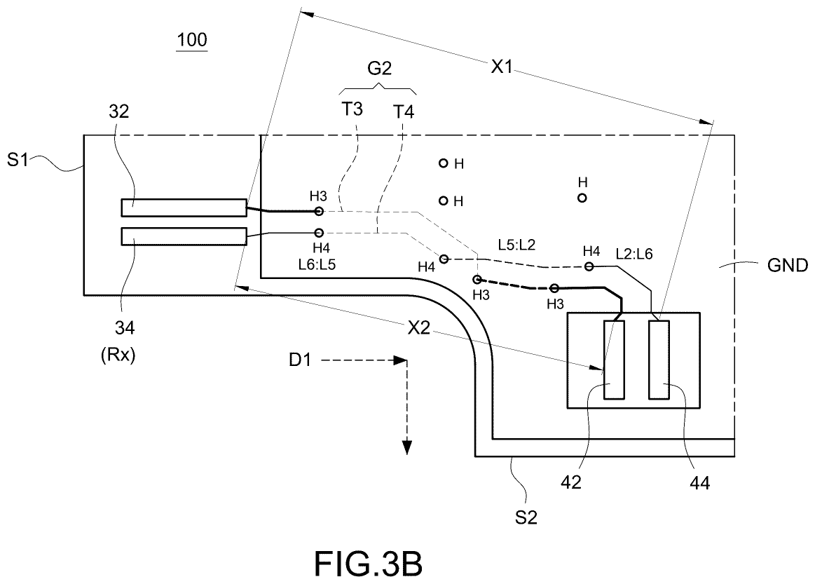

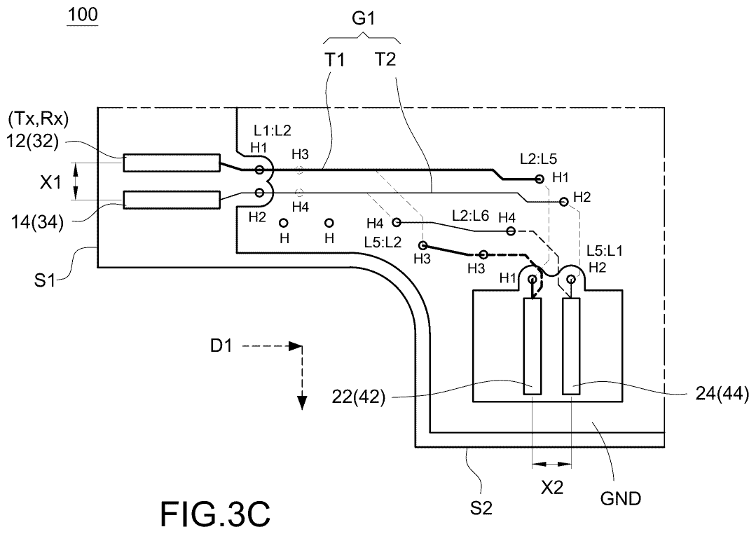

Please refer to FIG. 3A, which shows a diagram of the one trace layout of the side-exit circuit board according to a fourth embodiment of the present disclosure; please refer to FIG. 3B, which shows a diagram of the another trace layout of the side-exit circuit board according to a fourth embodiment of the present disclosure, and also refer to FIG. 1A to FIG. 2C. In FIG. 3A and FIG. 3B, which mainly show the signal terminals on an upper surface and a lower surface of the single-slice circuit board 100 and their trace configurations. Specifically, the most commonly used communication manner between chips is generally the universal asynchronous receiver/transmitter (UART), and its main feature is that only two wires (lines) are needed to complete two-way communication. Therefore, UART mainly uses one wire to receive signals and the other wire to transmit signals to complete the two-way communication, and the two wires are generally called Tx and Rx. Therefore, the configuration manners of FIG. 3A and FIG. 3B are mainly configured in response to Tx and Rx.

Furthermore, FIG. 3A is similar to FIG. 2A and includes a pair of first signal terminals, a pair of second signal terminals, a first trace assembly G1, and vias H1, H2. The pair of first signal terminals and the pair of second signal terminals form on a first surface layer L1 of the circuit board 100. FIG. 3B includes a pair of third signal terminals, a pair of fourth signal terminals, a second trace assembly G2, and vias H3, H4. The second trace assembly G2 includes a third trace T3 and a fourth trace T4. The pair of third signal terminals and the pair of fourth signal terminals form on a second surface layer L6 of the circuit board 100 (taking the circuit board 100 as a six-layer board as a schematic example), and the second surface layer L6 is different from the first surface layer L1.

Specifically, the pair of third signal terminals include a fifth terminal 32 and a sixth terminal 34, and the pair of fourth signal terminals include a seventh terminal 42 and an eighth terminal 44. The fifth terminal 32 and the sixth terminal 34 separately form on the second surface layer, and substantially at the same position as the first terminal 12 and the second terminal 14 on the first surface layer L1. That is, the pair of third signal terminal sand the pair of first signal terminals substantially overlap in top view. Similarly, the pair of fourth signal terminal sand the pair of second signal terminals substantially overlap in top view.

The extension sequence of the first trace T1 through the first vias H1 is L1:L2, L2:L5, L5:L1 so as to couple the first terminal 12 to the third terminal 22 through the first trace T1. The second terminal 14 is coupled to the fourth terminal 24 in a manner similar to the first trace T1, which will not be described again. The circuit board 100 further includes a plurality of third vias H3 and a plurality of fourth vias H4. The third trace T3 is similar to the first trace T1, and the third trace T3 is formed on the third specific layer (here represented by the sixth layer L6) of the circuit board 100, and extends to the fourth specific layer (here represented by the fifth layer L5) through one of the third vias H3. Moreover, regardless of the number of third vias H3 that the third trace T3 extends to different layers, it will ultimately return to the third specific layer through another third via H3 so that the fifth terminal 32 is electrically connected to the seventh terminal 42 through the third trace T3. The fourth trace T4 is similar to the second trace T2, and the fourth trace T4 is formed on the third specific layer (i.e., the sixth layer L6) of the circuit board 100, and extends to the fourth specific layer (i.e., the fifth layer L5) through one of the fourth vias H4. Moreover, regardless of the number of fourth vias H4 that the fourth trace T4 extends to different layers, it will ultimately return to the third specific layer through another fourth via H4 so that the sixth terminal 34 is electrically connected to the eighth terminal 44 through the fourth trace T4.

Specifically, the extension sequence of the third trace T3 through the third vias H3 is L6:L5, L5:L2, L2:L6 so as to couple the fifth terminal 32 to the seventh terminal 42 through the third trace T3. The sixth terminal 34 is coupled to the eighth terminal 44 in a manner similar to the third trace T3, which will not be described again. Therefore, the characteristics of the second trace assembly G2 are similar to those of the first trace assembly G1, that is, the third length of the third trace T3 is substantially equal to the fourth length of the fourth trace T4. In one embodiment, the first trace T1 and the second trace T2 extend from the surface layer (i.e., the first specific layer is the first layer L1) through the vias H1, H2 to other layers (i.e., the second layer), and finally return to the surface layer (that is, the same first specific layer) through the vias H1, H2 to electrically connect the terminals 12, 14, 22, 24 on the surface layer, but is not limited to this. That is, the above-mentioned surface layer is only a preferred embodiment. However, if the terminals 12, 14, 22, 24 are not arranged on the surface layer (i.e., the first specific layer is not the first layer L1), the first trace T1 and the second trace T2 may extend from the locations where the terminals 12, 14 are actually configured (such as but not limited to the second layer L2, the fifth layer L5, etc.) to other layers (i.e., the second specific layer). Finally, the actual locations of the terminals 22, 24 (such as but not limited to the third layer L3, the fourth layer L4, etc.) are electrically connected through the vias H1, H2. Moreover, the configuration of the third specific layer and the fourth specific layer is similar to the above-mentioned disclosure, that is, the above-mentioned surface layer is only a preferred embodiment. If the terminals 32, 34, 42, 44 are not arranged on the surface layer (i.e., the third specific layer is not the sixth layer L6), the third trace T3 and the fourth trace T4 may extend from the locations where the terminals 32, 34 are actually configured (such as but not limited to the third layer L3, the fourth layer L4, etc.) to other layers (i.e., the fourth specific layer). Finally, the actual locations of the terminals 42, 44 are electrically connected through the vias H3, H4.

Similar to FIG. 2A, the third trace T3 and the fourth trace T4 may be substantially in a parallel and equidistant trace structure. That is, the third trace T3 and the fourth trace T4 may form a parallel and equidistant trace structure on the linear extension section of the same layer. Moreover, due to the design of Tx and Rx, the first trace assembly G1 and the second trace assembly G2 are respectively used to transmit differential signals. Furthermore, the pair of first signal terminals may be used to transmit signals to the pair of second signal terminals, and the pair of fourth signal terminals may be used to transmit signals to the pair of third signal terminals to achieve a two-way communication function.

Please refer to FIG. 3C, which shows a diagram of the trace layer of overlapping circuits of FIG. 3A and FIG. 3B according to the fourth embodiment of the present disclosure, and also refer to FIG. 1A to FIG. 2C. The circuit board 100 of FIG. 3C is similar to that of FIG. 2A and includes a first ground layer and a second ground layer (not shown) that have the same and referenceable ground potential for differential signals of Tx and Rx (not shown in the figure). Similar to FIG. 2A, the first ground layer and the second ground layer may be formed on any layer except the surface layers L1, L6, and no trace of the first trace assembly G1 and the second trace assembly G2 is formed on the first ground layer and the second ground layer. Moreover, taking FIG. 3C as an example, the first ground layer and the second ground layer should be formed on the third layer L3 and the fourth layer L4, and may be electrically connected to the ground blocks GND of the surface layers L1, L6 through the vias H respectively.

Since the first trace T1 and the second trace T2 can pass through the first ground layer and the second ground layer through the extension of the first vias H1 and the second vias H2 (that is, the extension of L2:L5), and the third trace T3 and the fourth trace T4 can pass through the first ground layer and the second ground layer through the extension of the third vias H3 and the fourth vias H4 (that is, the extension of L5:L2), it means that although neither the first ground layer nor the second ground layer forms any trace of the first trace assembly G1 and the second trace assembly G2, the first ground layer and the second ground layer may still include vias H1-H4 for extending the traces T1-T4. Moreover, since the first trace assembly G1 and the second trace assembly G2 share the same layer (that is, they share the second layer L2 and the fifth layer L5), the traces of the two layers should be staggered, that is, the traces of the first trace assembly G1 and the second trace assembly G2 running on the two layers L2, L5 does not overlap.

Therefore, most of the traces in FIG. 3A to FIG. 3C are on the inner layers (i.e., the second layer L2 to the fifth layer L5), and it generally requires more than 12 vias H1-H4 to complete the connection of the pair of first signal terminals and the pair of second signal terminals. Moreover, the circuit board 100 uses the positions of the vias H1-H4 to be staggered so that the length of the first trace assembly G1 is similar to the length of the second trace assembly G2. Specifically, for the pair of first signal terminals and the pair of second signal terminals for Tx, the first trace T1 of the second layer L2 is shorter and the second trace T2 is longer. Moreover, the first trace T1 of the fifth layer L5 is longer, and the second trace T2 is shorter so that the total length of the first trace T1 is similar to the total length of the second trace T2. Relatively, the pair of third signal terminals and the pair of fourth signal terminals for Rx are exactly opposite to Tx and their total lengths are similar, which will not be described again here.

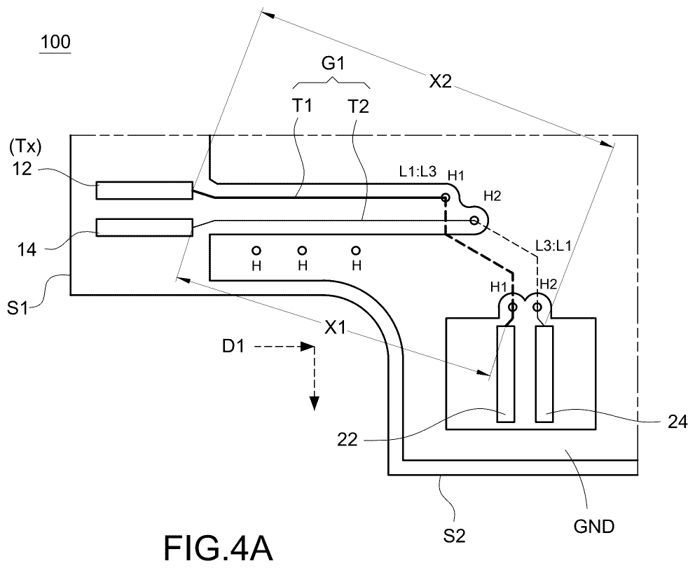

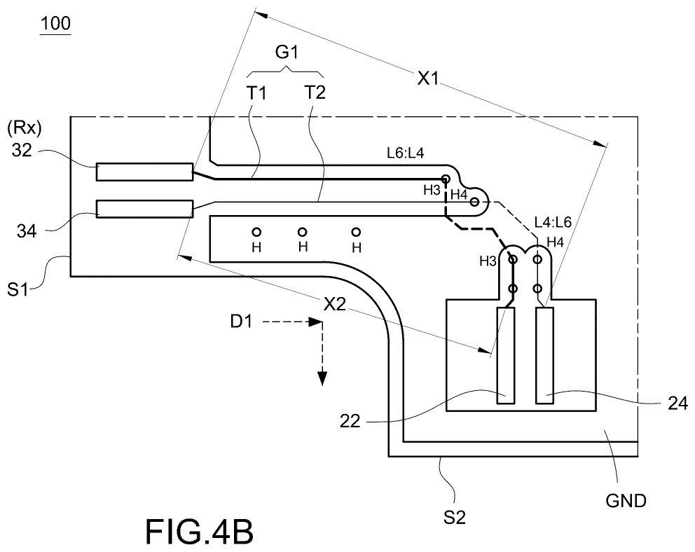

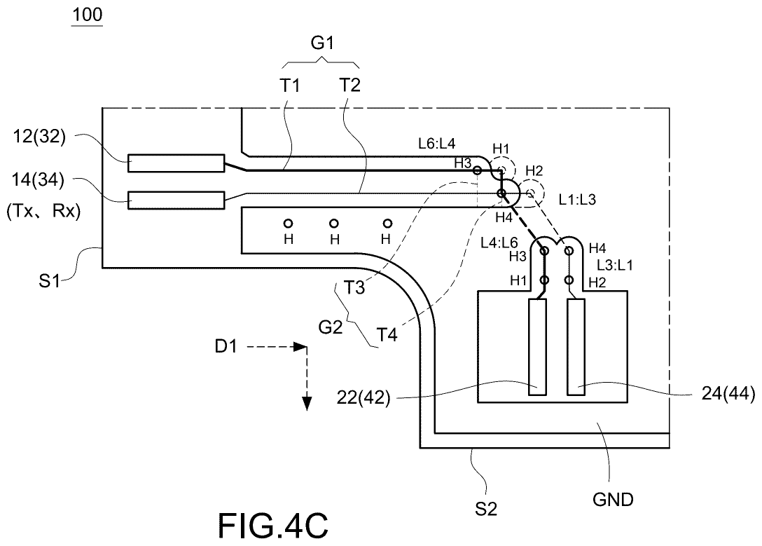

Please refer to FIG. 4A, which shows a diagram of the one trace layout of the side-exit circuit board according to a fifth embodiment of the present disclosure; please refer to FIG. 4B, which shows a diagram of the another trace layout of the side-exit circuit board according to a fifth embodiment of the present disclosure; please refer to FIG. 4C, which shows a diagram of the trace layer of overlapping circuits of FIG. 4A and FIG. 4B according to the fifth embodiment of the present disclosure, and also refer to FIG. 1A to FIG. 3C. The difference between FIG. 4A to FIG. 4C and FIG. 3A to FIG. 3C is that most of the traces T1-T4 in FIG. 4A to FIG. 4C are on the first surface layer L1 and the second surface layer L6. Moreover, the first trace assembly G1 is formed on an adjacent layer of the first ground layer, the second trace assembly G2 is formed on an adjacent layer of the second ground layer, and the first trace assembly G1 and the second trace assembly G2 are not formed on the same layer. Specifically, the extension sequence of the first trace T1 and the second trace T2 through the first vias H1 and the second vias H2 is L1:L3, L3:L1, and the first ground layer should be formed on the second layer L2. Relatively, the extension sequence of the third trace T3 and the fourth trace T4 through the third vias H3 and the fourth vias H4 is L6:L4, L4:L6, and the second ground layer should be formed on the fifth layer L5.

Since the first trace assembly G1 and the first ground layer are only formed on the first layer L1 to the third layer L3 of the circuit board 100, and the second trace assembly G2 and the second ground layer are only formed on the fourth layer L4 to the sixth layer L6, the first trace assembly G1 and the second trace assembly G2 do not share the same layer. Therefore, the first trace assembly G1 and the second trace assembly G2 may increase the number of vias without special detours, and therefore there is more space next to the traces to form vias H so that the first ground layer and the second ground layer can be electrically connected to the ground blocks GND of the surface layers L1, L6 respectively.

Therefore, most of the traces in FIG. 4A to FIG. 4C are on the outer layers (i.e., the first layer L1 and the sixth layer L6), and it generally requires more than 8 vias H1-H4 to complete the connection of the pair of first signal terminals and the pair of second signal terminals. In particular, wiring on the inner and outer layers each has its own advantages and disadvantages. When running on the inner layers, more vias H1-H4 are needed, and crosstalk is better; on the contrary, when running on the outer layers, fewer vias H1-H4 are needed, and the signal attenuation is low. Moreover, the circuit board 100 uses the positions of the vias H1-H4 to be staggered so that the length of the first trace assembly G1 is similar to the length of the second trace assembly G2. Specifically, for the pair of first signal terminals and the pair of second signal terminals for Tx, the first trace T1 of the second layer L2 is shorter and the second trace T2 is longer. Moreover, the first trace T1 of the surface layer L1 is shorter, and the second trace T2 is longer, and the first trace T1 of the third layer L3 is longer and the second trace T2 is shorter so that the total length of the first trace T1 is similar to the total length of the second trace T2. Relatively, the pair of third signal terminals and the pair of fourth signal terminals for Rx are exactly opposite to Tx and their total lengths are similar, which will not be described again here.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A circuit board, comprising:
a pair of first signal terminals, comprising a first terminal and a second terminal arranged in a specific direction from an edge of the circuit board, and the first terminal and the second terminal formed on a first side of the circuit board,
a pair of second signal terminals, comprising a third terminal and a fourth terminal arranged in the specific direction, wherein a first shortest distance between the first terminal and the fourth terminal is not the same as a second shortest distance between the second terminal and the third terminal, and
a first trace assembly, comprising:
a first trace, formed on a first specific layer of the board circuit, extending to a second specific layer of the board circuit through one of a plurality of first vias, and returning to the first specific layer through another of the plurality of first vias so as to electrically connect to the first terminal and the third terminal, and
a second trace, formed on the first specific layer, extending to the second specific layer through one of a plurality of second vias, and returning to the first specific layer through another of the plurality of second vias so as to electrically connect to the second terminal and the fourth terminal,
wherein the first trace has a first length and the second trace has a second length; the first trace and the second trace are formed on different layers in a staggered configuration, and the first length is substantially equal to the second length.

2. The circuit board as claimed in claim 1, wherein the third terminal and the fourth terminal are formed on a second side of the circuit board, and the first side is not parallel to the second side.

3. The circuit board as claimed in claim 2, wherein the first side is adjacent to the second side, and the first side is substantially 90 degrees to the second side.

4. The circuit board as claimed in claim 1, wherein the circuit board comprises a first surface layer and a second surface layer, and the circuit board further comprises:
a pair of third signal terminals, comprising a fifth terminal and a sixth terminal separately formed on the second surface layer, and substantially at the same position as the first terminal and the second terminal on the first surface layer,
a pair of fourth signal terminals, comprising a seventh terminal and an eighth terminal separately formed on the second surface layer, and substantially at the same position as the third terminal and the fourth terminal on the first surface layer,
a second trace assembly, comprising:
a third trace, formed on a third specific layer of the board circuit, extending to a fourth specific layer of the board circuit through one of a plurality of third vias, and returning to the third specific layer through another of the plurality of third vias so as to electrically connect to the fifth terminal and the seventh terminal, and
a fourth trace, formed on the third specific layer, extending to the fourth specific layer through one of a plurality of fourth vias, and returning to the third specific layer through another of the plurality of fourth vias so as to electrically connect to the sixth terminal and the eighth terminal,
wherein the third trace has a third length and the fourth trace has a fourth length, and the third length is substantially equal to the fourth length.

5. The circuit board as claimed in claim 4, further comprising:
a first ground layer, formed between the first surface layer and the second surface layer, and the first trace assembly and the second trace assembly not formed on the first ground layer, and
a second ground layer, adjacently formed to the first ground layer, and the first trace assembly and the second trace assembly not formed on the second ground layer.

6. The circuit board as claimed in claim 5, wherein the first trace assembly is formed on a layer adjacent to the first ground layer, the second trace assembly is formed on a layer adjacent to the second ground layer, and the first trace assembly and the second trace assembly are not formed on the same layer.

7. The circuit board as claimed in claim 4, wherein the pair of first signal terminals are configured to transmit signals to the pair of second signal terminals, and the pair of fourth signal terminals are configured to transmit signals to the pair of third signal terminals.

8. The circuit board as claimed in claim 4, wherein the first trace and the second trace are substantially in a parallel configuration, and the third trace and the fourth trace are substantially in a parallel configuration.
while the third and fourth wiring lines are situated in a parallel structure.

9. The circuit board as claimed in claim 4, wherein the first trace assembly and the second trace assembly are respectively configured to transmit a different signal.

10. The circuit board as claimed in claim 1, wherein the circuit board is a side-exit paddle card, and the paddle card is configured to connect to a connector.
